(19) United States
(12) Patent Application Publication
(10) Pub. No.: US 2016/0088722 A1
(43) Pub. Date: Mar. 24, 2016

(54) Rough Copper for Noise Reduction in High Speed Circuits

(71) Applicant: Dell Products, LP, Round Rock, TX (US)

(72) Inventors: Sandor Farkas, Round Rock, TX (US); Bhyrav M. Mutnury, Round Rock, TX (US)

(21) Appl. No.: 14/492,867

(22) Filed: Sep. 22, 2014

(51) Int. Cl. H05K 1/02; H05K 1/09; C25D 5/02; H05K 3/18; C25D 7/00

(52) U.S. Cl. CPC H05K 1/0216; H05K 3/188; C25D 7/00; C25D 5/02; H05K 1/09; H05K 2203/025; H05K 2203/0392; H05K 2201/0358

(57) ABSTRACT

A method includes providing, on a printed circuit board, a first copper layer having a first surface roughness, forming, by the first copper layer a power trace to a circuit device, providing, on the printed circuit board, a second copper layer having a second surface roughness, wherein the first surface roughness is greater than the second surface roughness, and forming, by the second copper layer, a signal trace to the circuit device.

### FIELD OF THE DISCLOSURE

This disclosure generally relates to information handling systems, and more particularly relates to a the use and application of rough copper in an information handling system printed circuit board.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

A printed circuit board for an information handling system can use copper traces for providing power and for carrying signals for the information handling system. The surface roughness of the copper has an impact on the performance of the traces. For example a copper trace with a smooth surface will exhibit lower insertion loss and less phase variation in the conducted signals than a similar copper trace with a rougher surface. Moreover, this effect is enhanced as the signal frequency is increased. This is because at higher signal frequencies the signals are conducted closer to the surface of the conductor, and so the profile of the copper surface has a greater impact on the signal quality.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 illustrates a printed circuit board that utilizes rough copper power layers according to an embodiment of the present disclosure;

FIG. 2 is a top view of a printed circuit board that utilizes a rough copper power layer according to an embodiment of the present disclosure;

FIG. 3 is a flowchart of a method for application of rough copper in an information handling system printed circuit board according to an embodiment of the present disclosure; and

FIG. 4 is a block diagram illustrating a generalized information handling system according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a laptop computer, a smart phone, a tablet device or other consumer electronic device, a network server, a network storage device, a switch router or other network communication device, or any other suitable device and may vary in size, shape, performance, functionality, and price. Further, an information handling system can include processing resources for executing machine-executable code, such as a central processing unit (CPU), a programmable logic array (PLA), an embedded device such as a System-on-a-Chip (SoC), or other control logic hardware. An information handling system can also include one or more computer-readable medium for storing machine-executable code, such as software or data. Additional components of an information handling system can include one or more storage devices that can store machine-executable code, one or more communications ports for communicating with external devices, and various input and output (I/O) devices, such as a keyboard, a mouse, and a video display. An information handling system can also include one or more buses operable to transmit information between the various hardware components.

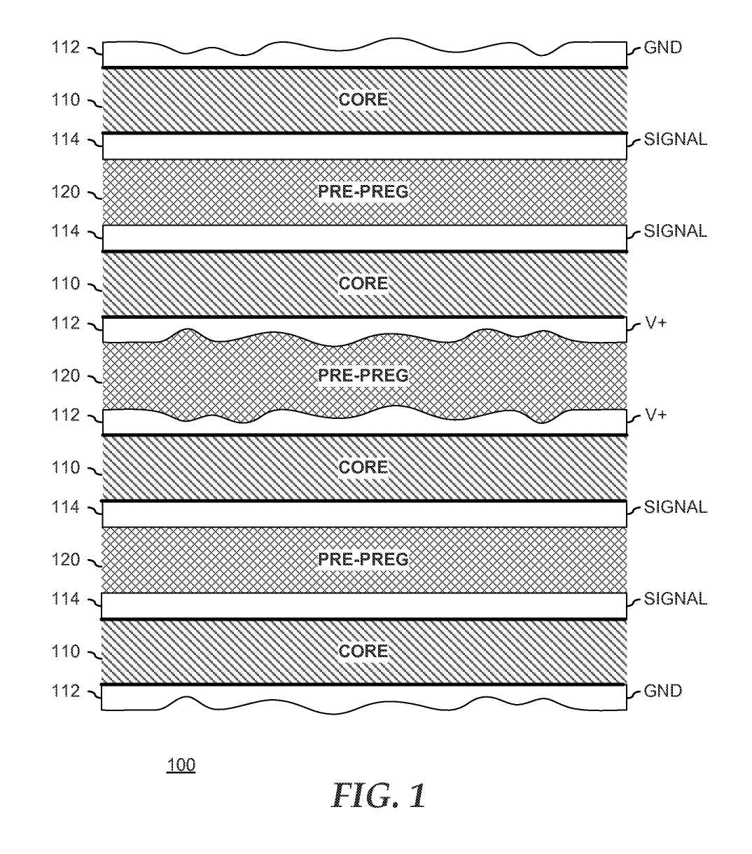

FIG. 1 illustrates a printed circuit board 100 that can be utilized in an information handling system, including core layers 110 interleaved with pre-impregnated composite fiber (pre-preg) layers 120. Core layers 110 represent two-sided copper-clad laminate layers upon which power plane traces 112 and circuit traces 114 are etched. Pre-preg layers 120 represent a laminate layer that does not include circuit traces, and that provides separation between the circuit traces of core layers 110. An example of a laminate layer includes an epoxy laminate, a composite fiber laminate, a FR-2 laminate, a FR-4 laminate, or another laminate material, as needed or desired, and can include a composite fiber matrix such as fiberglass cloth, carbon fiber matrix, that is pre-impregnated with the laminate material. The illustrated embodiment of printed circuit board 100 is an eight layer printed circuit board, that is, the printed circuit board has eight copper layers separated by seven laminate layers. The skilled artisan will recognize that a printed circuit board with greater or fewer than eight layers can be provided, as needed or desired.

In manufacturing, a typical core layer 110 will be assembled with a coating of copper on the two surfaces of the core layer, a pattern of circuit traces will be provided on the copper coatings, and the excess copper from the two sides will be etched off of the surfaces to leave power plane trace 112 and circuit trace 114. Note that, while being described as a single power plane trace and a single circuit trace, in application, power plane trace 112 and circuit trace 114 will include multiple circuit traces, as needed or desired. With each of the four core layers 110 patterned with their associated traces 112 and 114, the four core layers are interleaved with three pre-preg layers 114, and the entire assembly is bonded together, typically using a pressure process, to make the completed printed circuit board 100.

Power plane layers 112 are illustrated as having a rough copper surface, while trace layers 114 are illustrated as having smooth copper layers. Note that the surface profiles of traces 112 and 114 in printed circuit board 100 are greatly exaggerated for the purpose of illustration, and that the relative roughness or smoothness of layers 112 and 114 would likely appear similar upon unaided visual inspection. The surface roughness of traces 112 and 114 are measured based upon a particular profile roughness parameter. An example of a profile roughness parameter includes an arithmetic average of absolute values parameter (Rₐ), a root mean square parameter (R_{q}), a skewness parameter (Rₛₖ), or another profile roughness parameter, as needed or desired.

In a particular embodiment, the copper coatings that are used to make traces 112 and 114 are commercially available copper coatings, such as rolled copper foils with an R_{q} surface roughness of around 0.4 micrometers (μm), electrodeposited copper foils with an R_{q} surface roughness of around 0.5 to 3.5 μm, and resistive copper foils with an R_{q} surface roughness of around 1.0 to 2.0 μm. Here, for example, power trace 112 can be manufactured using a rough copper coating such as an electrodeposited copper foil with an R_{q} surface roughness at the higher end of the available coatings, such as with an R_{q} of between 1.5 and 3.5 μm, or such as a resistive foil with a similar R_{q} value. Further, circuit trace 114 can be manufactured using a smooth copper coating such as a rolled copper foil with an R_{q} surface roughness of around 0.4, or such as an electrodeposited copper foil with an R_{q} surface roughness at the lower end of the available coatings, such as with an R_{q} of between 0.5 and 1.5 μm.

In another embodiment, the copper coatings that are used to make traces 112 and 114 are commercially available copper coatings, and power trace 114 is further processed to increase the surface roughness. For example, a copper coating for both power trace 112 and circuit trace 114 can be selected that has a relatively smooth surface roughness, and the copper coating of power trace 112 can be mechanically or chemically roughened to provide a surface roughness of around 25 μm. In this way, a common processing methodology to adhere the copper coatings for both power trace 112 and circuit trace 114, and then the additional processing can be performed only on the power trace 112.

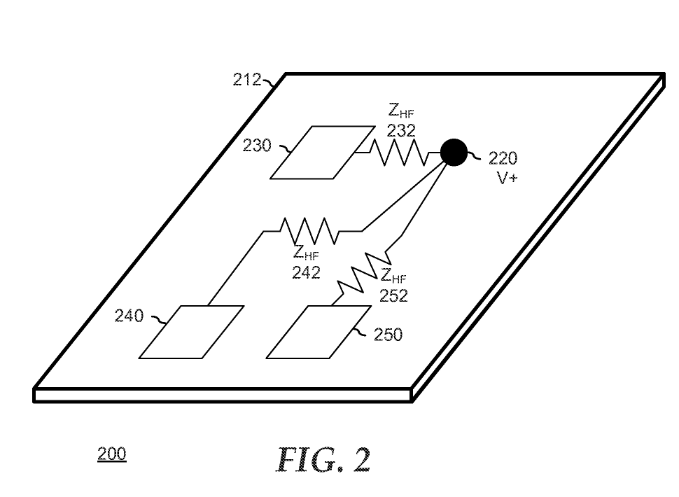

FIG. 2 illustrates a printed circuit board 200 similar to printed circuit board 100, including a rough copper power trace 212 similar to one of power trace 112. Power trace 212 includes a power node 220 that can represent a voltage supply plane, such as a positive voltage level power plane, as illustrated, or can represent a reference voltage plane, such as a circuit ground. Power trace 212 provides one or more circuit power nodes for devices 230, 240, and 250, to provide direct current (DC) power to the devices. For example, device 230 can represent a processor of an information handling system, device 240 can represent a memory device of the information handling system, and device 250 can represent an I/O bridge device of the information handling system.

Devices 230, 240, and 250 include one or more high speed data interfaces that operate to rapidly move data between the devices. The data is transferred on signal traces, not shown, of printed circuit board 200. Thus, due to cross-talk effects and other coupling effects, power trace 212 can provide an undesirable high frequency element to devices 230, 240, and 250. For example, if via cross-talk between a signal trace and power trace 212, a high frequency signal from device 230 is injected into the power trace, the high frequency signal can be provided to the vie power node 220 to the circuit power node of device 240 as an undesirable power supply noise component.

However, because power trace 212 is formed using rough copper, the insertion loss of the rough copper operates to dampen the high frequency signal and clean up the power delivered to devices 230, 240, and 250. Thus power node 220 is shown schematically as being connected to device 230 via a high frequency impedance 232, to device 240 via a high frequency impedance 242, and to device 250 via a high frequency impedance 252.

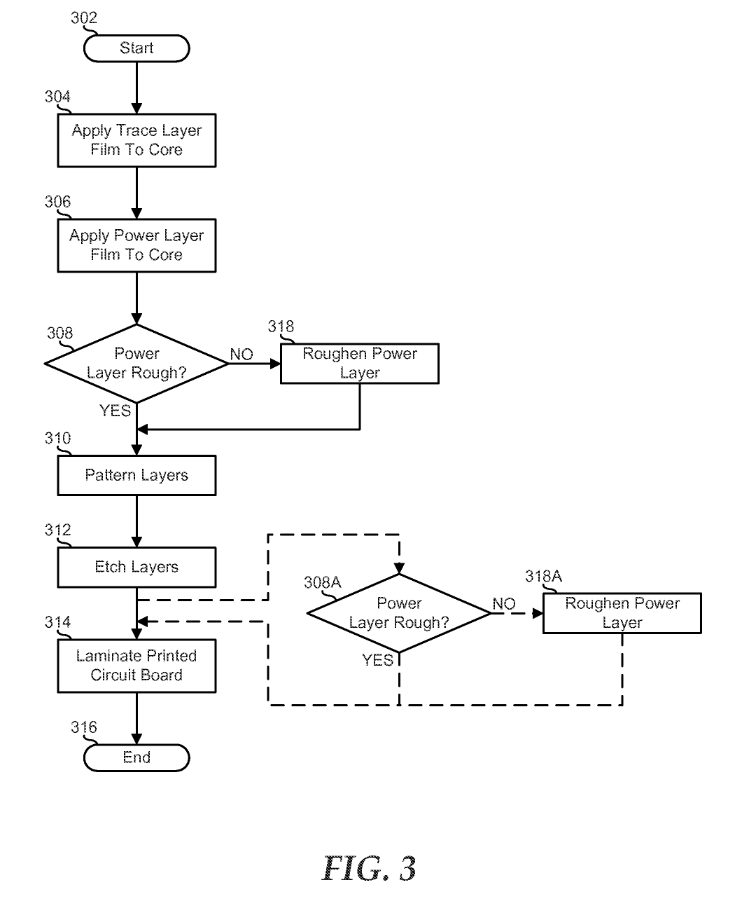

FIG. 3 illustrates a method for application of rough copper in an information handling system printed circuit board beginning at block 302. A trace layer copper film is applied to a core in block 304. A power layer copper film is applied to the core in block 306. A decision is made as to whether or not the power layer copper film is a rougher copper layer than the trace layer copper film in decision block 308. If not, the “NO” branch of decision block 308 is taken and the power layer is roughened in block 318, and the method proceeds to block 310, as described below. If the power layer copper film is a rougher copper layer than the trace layer copper film, the “YES” branch of decision block 308 is taken, trace patterns are applied to the trace layer and the power layer in block 310, and the patterns are etched into the trace layer copper film and the power layer copper film in block 312. The core layer is laminated into a printed circuit board in block 314 and the method ends in block 316. In an alternate embodiment, the decision as to whether or not the power layer copper film is a rougher copper layer than the trace layer copper film is made after the traces are etched into the copper films, as shown in decision block 308A, and any needed roughening of the power layer, as shown in block 318A, is performed on the etched circuit traces, rather than on the unpatterned copper layers.

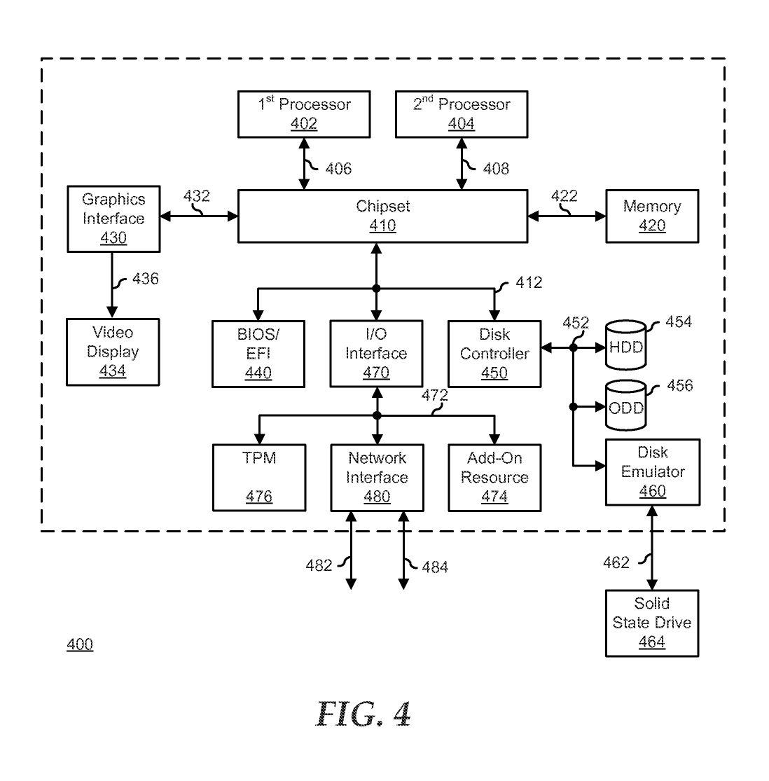

FIG. 4 illustrates a generalized embodiment of information handling system 400. For purpose of this disclosure information handling system 400 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 400 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 400 can include processing resources for executing machine-executable code, such as a central processing unit (CPU), a programmable logic array (PLA), an embedded device such as a System-on-a-Chip (SoC), or other control logic hardware. Information handling system 400 can also include one or more computer-readable medium for storing machine-executable code, such as software or data. Additional components of information handling system 400 can include one or more storage devices that can store machine-executable code, one or more communications ports for communicating with external devices, and various input and output (I/O) devices, such as a keyboard, a mouse, and a video display. Information handling system 400 can also include one or more buses operable to transmit information between the various hardware components.

Information handling system 400 can include devices or modules that embody one or more of the devices or modules described above, and operates to perform one or more of the methods described above. Information handling system 400 includes a processors 402 and 404, a chipset 410, a memory 420, a graphics interface 430, include a basic input and output system/extensible firmware interface (BIOS/EFI) module 440, a disk controller 450, a disk emulator 460, an input/output (I/O) interface 470, and a network interface 480. Processor 402 is connected to chipset 410 via processor interface 406, and processor 404 is connected to the chipset via processor interface 408. Memory 420 is connected to chipset 410 via a memory bus 422. Graphics interface 430 is connected to chipset 410 via a graphics interface 432, and provides a video display output 436 to a video display 434. In a particular embodiment, information handling system 400 includes separate memories that are dedicated to each of processors 402 and 404 via separate memory interfaces. An example of memory 420 includes random access memory (RAM) such as static RAM (SRAM), dynamic RAM (DRAM), non-volatile RAM (NV-RAM), or the like, read only memory (ROM), another type of memory, or a combination thereof.

BIOS/EFI module 440, disk controller 450, and I/O interface 470 are connected to chipset 410 via an I/O channel 412. An example of I/O channel 412 includes a Peripheral Component Interconnect (PCI) interface, a PCI-Extended (PCI-X) interface, a high-speed PCI-Express (PCIe) interface, another industry standard or proprietary communication interface, or a combination thereof. Chipset 410 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/EFI module 440 includes BIOS/EFI code operable to detect resources within information handling system 400, to provide drivers for the resources, initialize the resources, and access the resources. BIOS/EFI module 440 includes code that operates to detect resources within information handling system 400, to provide drivers for the resources, to initialize the resources, and to access the resources.

Disk controller 450 includes a disk interface 452 that connects the disc controller to a hard disk drive (HDD) 454, to an optical disk drive (ODD) 456, and to disk emulator 460. An example of disk interface 452 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 460 permits a solid-state drive 464 to be connected to information handling system 400 via an external interface 462. An example of external interface 462 includes a USB interface, an IEEE 1394 (Firewire) interface, a proprietary interface, or a combination thereof. Alternatively, solid-state drive 464 can be disposed within information handling system 400.

I/O interface 470 includes a peripheral interface 472 that connects the I/O interface to an add-on resource 474, to a TPM 476, and to network interface 480. Peripheral interface 472 can be the same type of interface as I/O channel 412, or can be a different type of interface. As such, I/O interface 470 extends the capacity of I/O channel 412 when peripheral interface 472 and the I/O channel are of the same type, and the I/O interface translates information from a format suitable to the I/O channel to a format suitable to the peripheral channel 472 when they are of a different type. Add-on resource 474 can include a data storage system, an additional graphics interface, a network interface card (NIC), a sound/video processing card, another add-on resource, or a combination thereof. Add-on resource 474 can be on a main circuit board, on separate circuit board or add-in card disposed within information handling system 400, a device that is external to the information handling system, or a combination thereof.

Network interface 480 represents a NIC disposed within information handling system 400, on a main circuit board of the information handling system, integrated onto another component such as chipset 410, in another suitable location, or a combination thereof. Network interface device 480 includes network channels 482 and 484 that provide interfaces to devices that are external to information handling system 400. In a particular embodiment, network channels 482 and 484 are of a different type than peripheral channel 472 and network interface 480 translates information from a format suitable to the peripheral channel to a format suitable to external devices. An example of network channels 482 and 484 includes InfiniBand channels, Fibre Channel channels, Gigabit Ethernet channels, proprietary channel architectures, or a combination thereof. Network channels 482 and 484 can be connected to external network resources (not illustrated). The network resource can include another information handling system, a data storage system, another network, a grid management system, another suitable resource, or a combination thereof.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method comprising:
providing, on a printed circuit board, a first copper layer having a first surface roughness;
forming, by the first copper layer a power trace to a circuit device;
providing, on the printed circuit board, a second copper layer having a second surface roughness, wherein the first surface roughness is greater than the second surface roughness; and
forming, by the second copper layer, a signal trace to the circuit device.

2. The method of claim 1, wherein in providing the first copper layer the method further comprises:
providing, on the printed circuit board, the first copper layer having a third surface roughness, wherein the first surface rough is greater than the third surface roughness; and
roughening the first copper layer to the first surface roughness.

3. The method of claim 2, wherein roughening the first copper layer comprises a mechanical roughening process.

4. The method of claim 2, wherein roughening the first copper layer comprises an etching process.

5. The method of claim 1, wherein the first surface roughness has a root mean square roughness (R_{q}) value between 3.5 and 25 micrometers (μm).

6. The method of claim 5, wherein the second surface roughness has a R_{q} value between 0.4 and 1.5 micrometers (μm).

7. The method of claim 1, wherein the first copper layer and the second copper layer each comprise one of a rolled copper foil, an electrodeposited copper foil, and a resistive copper foil.

8. The method of claim 1, wherein the first copper layer operates dampen a high frequency signal component in the power provided to the circuit device.

9. The method of claim 8, wherein the high frequency signal component is received via cross-talk from the signal trace.

10. A printed circuit board, comprising:
a circuit device; and
a copper-clad laminate core, comprising:
a first copper layer having a first surface roughness including a power trace operable to provide power to the circuit device; and
a second copper layer having a second surface roughness including a signal trace operable go conduct a signal of the circuit device,
wherein the first surface roughness is greater than the second surface roughness.

11. The printed circuit board of claim 10, wherein the first surface roughness has a root mean square roughness (R_{q}) value between 3.5 and 25 micrometers (μm).

12. The printed circuit board of claim 11, wherein the second surface roughness has a R_{q} value between 0.4 and 1.5 micrometers (μm).

13. The printed circuit board of claim 10, wherein the first copper layer and the second copper layer each comprise one of a rolled copper foil, an electrodeposited copper foil, and a resistive copper foil.

14. The printed circuit board of claim 10, wherein the first copper layer operates dampen a high frequency signal component in the power provided to the circuit device.

15. The printed circuit board of claim 14, wherein the high frequency signal component is received via cross-talk from the signal trace.

16. A laminate core of a printed circuit board, comprising:
a first copper layer having a first surface roughness including a power trace operable to provide power to a circuit device; and
a second copper layer having a second surface roughness including a signal trace operable go conduct a signal of the circuit device, wherein the first surface roughness is greater than the second surface roughness.

17. The laminate core of claim 16, wherein the first surface roughness has a root mean square roughness (R_{q}) value between 3.5 and 25 micrometers (μm).

18. The laminate core of claim 17, wherein the second surface roughness has a R_{q} value between 0.4 and 1.5 micrometers (μm).

19. The laminate core of claim 16, wherein the first copper layer and the second copper layer each comprise one of a rolled copper foil, an electrodeposited copper foil, and a resistive copper foil.

20. The laminate core of claim 16, wherein the first copper layer operates dampen a high frequency signal component in the power provided to the circuit device.
